(19) United States
(12) Patent Application Publication
(10) Pub. No.: US 2025/0253814 A1
(43) Pub. Date: Aug. 7, 2025

(54) LOW-NOISE LINEAR DYNAMIC AMPLIFIER

(71) Applicant: QUALCOMM Incorporated, San Diego, CA (US)

(72) Inventors: Hanyu WANG, Corvallis, OR (US); Behnam SEDIGHI, La Jolla, CA (US); Kentaro YAMAMOTO, San Diego, CA (US); Dan YUAN, San Diego, CA (US)

(21) Appl. No.: 18/432,520

(22) Filed: Feb. 5, 2024

(51) Int. Cl. H03F 3/45; H03F 1/30

(52) U.S. Cl. CPC H03F 3/45183; H03F 1/303; H03F 2200/372; H03F 2203/45288

(57) ABSTRACT

Certain aspects are directed towards amplifiers and techniques for signal amplification. An example amplifier generally includes: a first capacitive element coupled to a first output of the amplifier; a first switch coupled between the first capacitive element and a voltage rail; a transconductance amplifier including a first flipped source follower circuit; a second switch coupled between the first capacitive element and the transconductance amplifier; and switches to activate the transconductance amplifier.

### TECHNICAL FIELD

Certain aspects of the present disclosure generally relate to electronic circuits and, more particularly, to an amplifier.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more amplifiers for signal amplification.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include increased linearity and decreased noise.

Certain aspects are directed towards an amplifier. The amplifier generally includes: a first capacitive element coupled to a first output of the amplifier; a first switch coupled between the first capacitive element and a voltage rail; a transconductance amplifier including a first flipped source follower circuit; and a second switch coupled between the first capacitive element and the transconductance amplifier.

Certain aspects are directed towards a method for signal amplification. The method generally includes: charging a first capacitive element coupled to a first output of an amplifier during a charging phase; generating a first current via a transconductance amplifier including a first flipped source follower circuit; and discharging the first capacitive element using the first current during a discharging phase.

Certain aspects are directed towards an apparatus for signal amplification. The apparatus generally includes a memory and one or more processors coupled to the memory, the one or more processors being configured to: control a first switch coupled between a capacitive element and a voltage rail to charge a capacitive element during a charge phase; activate a transconductance amplifier including a flipped source follower circuit to generate a current; and control a second switch coupled between the capacitive element and the transconductance amplifier to discharge the capacitive element using the current.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 illustrates an example amplifier, in accordance with certain aspects of the present disclosure.

FIG. 5 is a timing diagram illustrating timing of signals used to control an amplifier, in accordance with certain aspects of the present disclosure.

FIG. 6 illustrates output voltages of an amplifier, in accordance with certain aspects of the present disclosure.

FIG. 7 illustrates an example amplifier implemented with a common current source, in accordance with certain aspects of the present disclosure.

FIG. 8 is a flow diagram illustrating example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards an amplifier implemented using capacitor discharge via a transconductance amplifier implemented with a flipped source follower for improved linearity. For example, the transconductance amplifier may include a differential pair coupled to a differential flipped source follower, providing increased linearity for converting a differential input voltage to a differential current. The differential current may be used to discharge a capacitive element to generate a differential output voltage for the amplifier. In some aspects, a common current source may be used to generate the positive and negative voltages of the differential output voltage of the amplifier. In this manner, noise from the current source may be common to the positive and negative voltages, reducing the noise associated with the differential output voltage. As used herein, a flipped source follower (FSF) (e.g., also referred to as a “flipped voltage follower”) generally refers to a source follower transistor with a feedback transistor coupled to a source of the source follower transistor.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

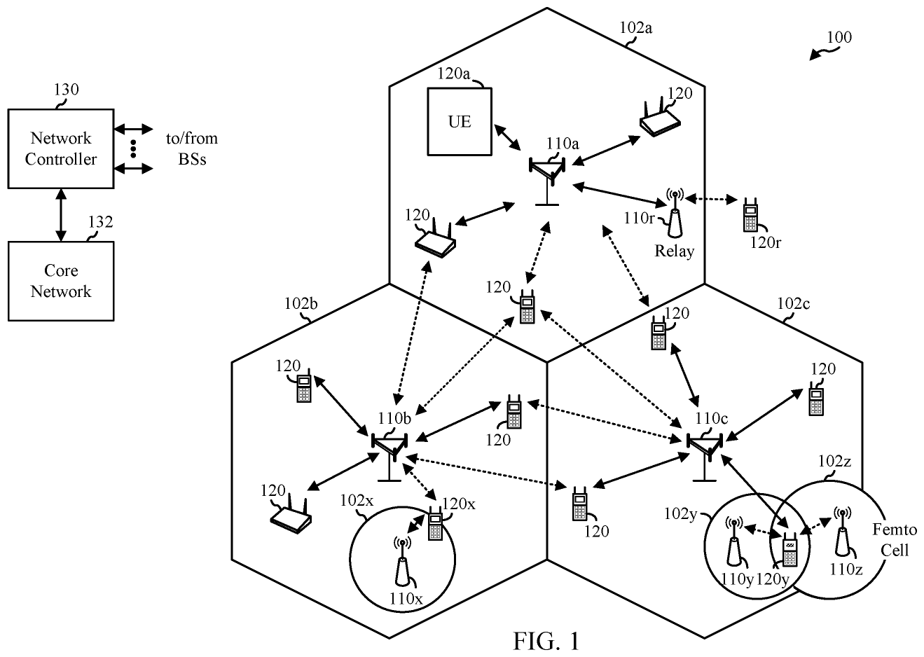

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to Nan, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nap of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include an amplifier implemented using capacitor discharge with a transconductance amplifier having a flipped source follower for improved linearity, as described in more detail herein.

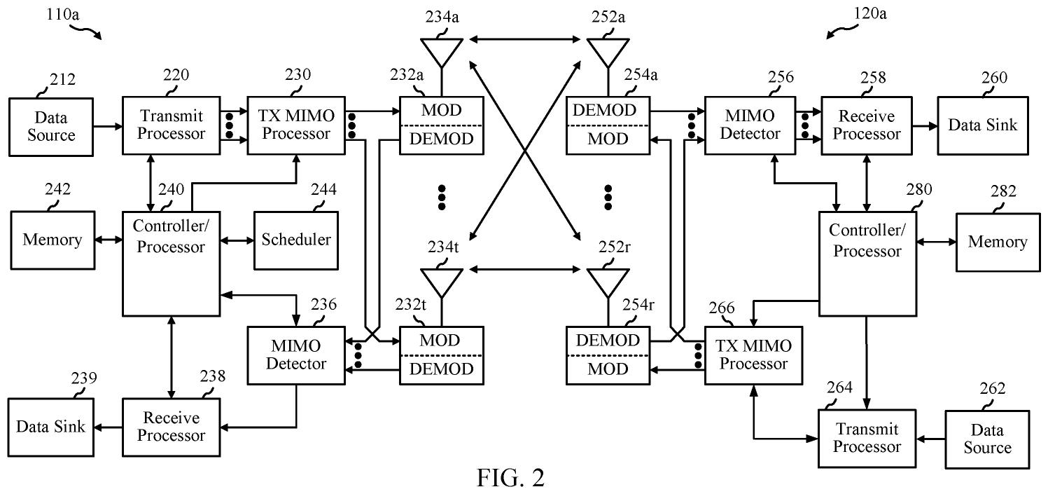

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may include an amplifier implemented using capacitor discharge with a transconductance amplifier having a flipped source follower for improved linearity, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

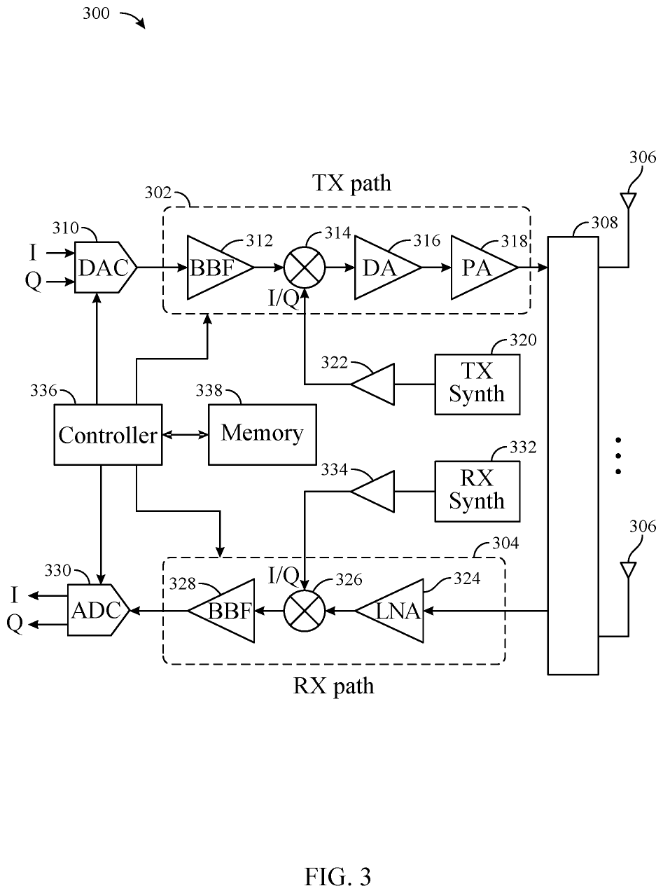

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing. In some aspects, the ADC may include a residual amplifier (e.g., in a pipelined ADC) implemented using capacitor discharge with a transconductance amplifier having a flipped source follower for improved linearity, as described in more detail herein.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems.

### Example Low-Noise Linear Dynamic Amplifier

Open-loop amplifiers could, for example, be used as residue amplifiers in a pipelined analog-to-digital converter (ADC), where a pipelined ADC could be used to implement the ADC 330 of FIG. 3. Any noise or nonlinearity of the amplifier may degrade the signal-to-noise-and-distortion ratio (SNDR) of the ADC. In traditional open-loop dynamic amplifiers, the linearity of the input-output characteristic of the amplifier is degraded by the non-linear nature of metal-oxide-semiconductor (MOS) transistors. Previous solutions for reducing distortion in dynamic amplifiers have involved trading off high noise for increased linearity. Certain aspects of the present disclosure are directed towards an amplifier with increased linearity and decreased noise as compared to conventional implementations.

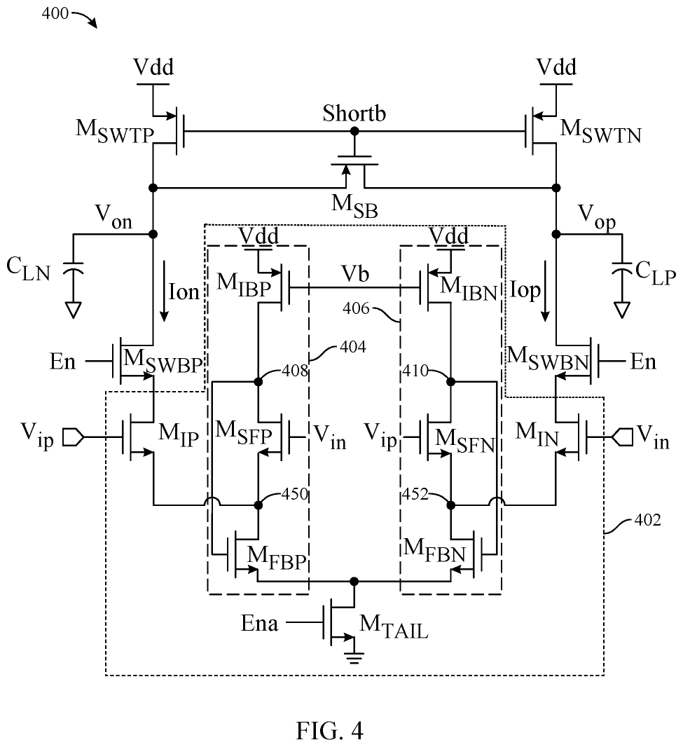

FIG. 4 illustrates an example amplifier 400, in accordance with certain aspects of the present disclosure. The amplifier 400 may include a positive top switch implemented using a p-type metal-oxide-semiconductor (PMOS) transistor (M_{SWTP}) coupled between a voltage rail Vdd and a negative output voltage (Vₒₙ) node and a negative top switch implemented using a PMOS transistor (M_{SWTN}) coupled between Vdd and a positive output voltage (Vₒₚ) node. Capacitive elements C_{LN} and C_{LP} may be coupled between a reference potential node (e.g., electrical ground) and a respective one of the Vₒₙ node and the Vₒₚ node. In some aspects, capacitive elements C_{LN} and C_{LP} may be charged to Vdd by turning on transistors M_{SWTP}, M_{SWTN} during a charging phase. Then, a transconductance (Gm) amplifier 402 may be used to sink output currents Ion and Iop from respective capacitive elements C_{LN} and C_{LP}, discharging the capacitive elements C_{LN} and C_{LP} for a time period (Tₐₘₚ). At the end of Tₐₘₚ, the voltage at the Vₒₚ node and the Vₒₙ node represent an output differential voltage of the amplifier 400. The gain of the amplifier 400 may be represented by equation:

$$Gain = \frac{{G}_{m} {T}_{amp}}{{C}_{L}}$$

where Gm is the transconductance of amplifier 402, and C_{L} is the capacitance of capacitive elements C_{LN} and C_{LP} which may be the same.

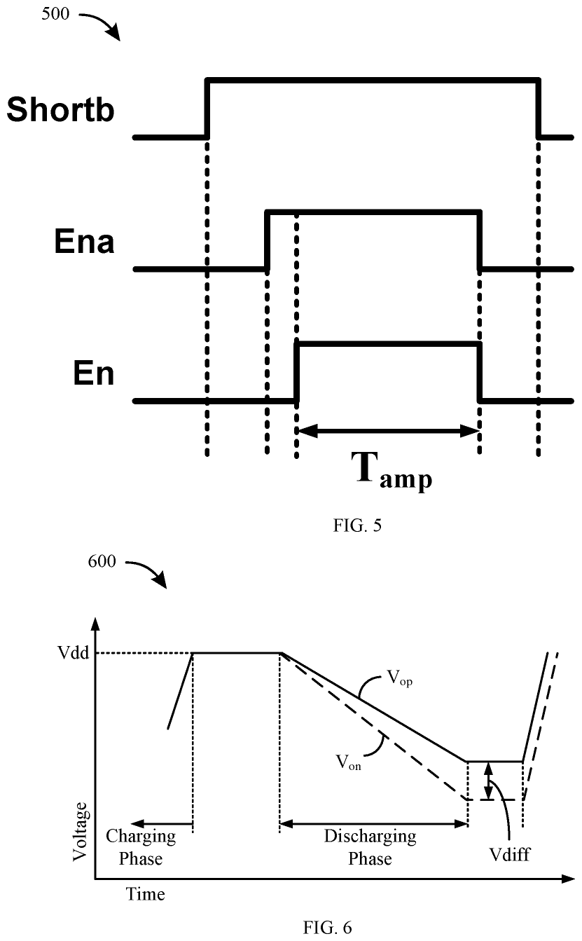

FIG. 5 is a timing diagram 500 illustrating timing of signals used to control the amplifier 400. The signals described with respect to diagram 500 may be controlled by a controller. As shown, when logic low, the Shortb signal is used to turn on PMOS transistors M_{SWTP}, M_{SWTN}, effectively shorting the capacitive elements C_{LN} and C_{LP} to Vdd during a pre-charging phase. In some aspects, as shown in FIG. 4, a PMOS transistor M_{SB} may be coupled between the Vₒₙ node and the Vₒₚ node. Transistor M_{SB} may be turned on via the Shortb signal when the capacitive elements C_{LN} and C_{LP} are being charged so that the capacitive elements C_{LN} and C_{LP} are pre-charged to the same voltage level.

As shown in FIG. 4, the amplifier 400 may include a positive bottom switch implemented using a NMOS transistor (M_{SWBP}) and a negative bottom switch implemented using a NMOS transistor (M_{SWBN}) coupled between amplifier 402 and a respective one of the Vₒₙ node and the Vₒₚ node. During a discharging phase, the transistors M_{SWBP} and M_{SWBN} may be turned on using an enable (En) signal to begin discharging the capacitive elements C_{LN} and C_{LP}.

As shown, the transconductance amplifier 402 receives differential input voltages Vᵢₚ and Vᵢₙ (e.g., at a differential input pair) at respective gates of input transistors M_{IP} and M_{IN} and generates the output currents Ion and Iop used to discharge respective capacitive elements C_{LN} and C_{LP}. The input transistors M_{IP} and M_{IN} include drains coupled to sources of transistors M_{SWBP} and M_{SWBN}, respectively. The amplifier 402 employs a differential flipped source follower (DFSF) circuit to assist the Gm input devices (e.g., transistors M_{IP} and M_{IN}). For example, the amplifier 402 may include a flipped source follower (FSF) circuit 404 and FSF circuit 406 coupled to respective input transistors M_{IP} and M_{IN}. The FSF circuits 404, 406 include respective current sources (e.g., constant current sources implemented via respective transistors M_{IBP} and M_{IBN}). Transistors M_{IBP} and M_{IBN} may be PMOS transistors having sources coupled to Vdd and drains coupled to respective nodes 408, 410. The gates of transistors M_{IBP} and M_{IBN} receive a bias voltage V_{b}, as shown. The nodes 408, 410 are coupled to respective drains of positive and negative source follower (SF) transistors M_{SFP} and M_{SFN}, as well as to respective gates of positive and negative feedback transistors M_{FBP} and M_{FBN}. The gates of transistors M_{FBP} and M_{FBN} receive respective input voltages Vᵢₙ and Vᵢₚ. The drains of transistors M_{FBP} and M_{FBN} are coupled to respective FSF output nodes 450, 452. The output nodes 450, 452 are coupled to respective sources of transistors M_{SFP} and M_{SFN} and to respective sources of transistors M_{IP} and M_{IN}, where transistors M_{IP} and M_{IN} implement a differential pair (DP). The sources of transistors M_{FBP} and M_{FBN} are coupled to a tail current source implemented via transistor M_{TAIL}. The gate of transistor M_{TAIL} may receive another enable signal (Ena) to activate the amplifier 402.

As shown in FIG. 5, the Shortb signal is logic low during a pre-charging phase to charge the capacitive elements C_{LN} and C_{LP}, after which the Shortb signal transitions to logic high to end the pre-charging phase (e.g., turn off transistors M_{SWTP}, M_{SWTN}, and M_{SB}). Once the charging phase has ended, the Ena signal transitions to logic high to activate the amplifier 402. After a certain amount of delay (to account for settling time after activation of the amplifier 402), the En signal transitions to logic high to turn on transistors M_{SWBP}, M_{SWBN} and begins the discharging phase during which the capacitive elements C_{LN} and C_{LP} are discharged. After amplification, the amplifier has little to no static current consumption since Ena becomes logic low, and M_{TAIL} is switched off.

FIG. 6 is a graph 600 illustrating output voltages Vₒₚ and Vₒₙ, in accordance with certain aspects of the present disclosure. As shown, during the pre-charging phase, output voltages Vₒₚ and Vₒₙ increase to Vdd. Once the En signal transitions to logic high starting the discharging phase, output voltages Vₒₚ and Vₒₙ decrease at different rates until the discharging phase ends (e.g., after Tₐₘₚ). The difference between output voltages Vₒₚ and Vₒₙ represents the differential output voltage (Vdiff) of the amplifier 400.

Some aspects of the present disclosure are directed towards techniques for reducing the noise associated with the amplifier described herein. The differential current source implemented via transistors M_{IBP} and M_{IBN} contributes noise to the amplifier 400, which may be as large as the noise contributed by the input devices (e.g., transistors M_{IP}, M_{IN}, M_{SFP}, and M_{SFN}). In some aspects, the transistors M_{IBP} and M_{IBN} may be replaced with a single transistor sourcing current to both FSF circuits 404, 406 so that the noise from the current source is a common-mode noise (e.g., common to both FSF circuits 404, 406) instead of differential noise, reducing the differential output noise of the amplifier.

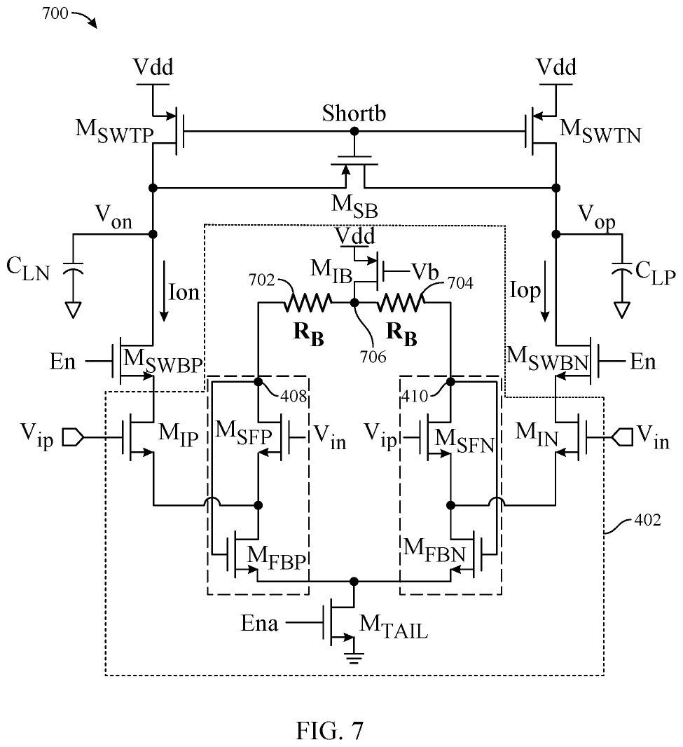

FIG. 7 illustrates an example amplifier 700 implemented with a common current source, in accordance with certain aspects of the present disclosure. For example, the amplifier 700 may include a current source implemented via a PMOS transistor M_{IB} with a source coupled to Vdd and a drain coupled to node 706. The node 706 may be coupled to respective nodes 408, 410 via respective resistive elements 702, 704 which may have the same resistance RB. In this manner, the current from the current source (transistor MB) may be split equally to nodes 408, 410, and thus, the noise from the current source may be common to both output voltages Vₒₚ and Vₒₙ, reducing the impact of the noise on the differential output voltage Vdiff.

Certain aspects provide an amplifier with increased linearity by using a DFSF circuit. The amplifier described herein is implemented with DP-based transconductance (e.g., using transistors M_{IP} and M_{IN}) for discharging capacitive elements C_{LN} and C_{LP}, which provides low-voltage-supply compatibility. Certain aspects also provide an amplifier with reduced noise as compared to some conventional implementations. For example, by replacing two current sources (e.g., transistor M_{IBP} and M_{IBN} of FIG. 4) with a common-mode current source (e.g., current source M_{IB} of FIG. 7) and a pair of linear resistive elements (e.g., resistive elements 702, 704 of FIG. 7), the differential noise of the amplifier may be reduced.

### Example Operations for Signal Amplification

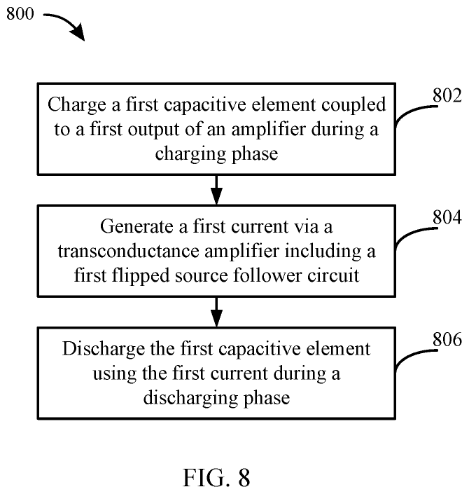

FIG. 8 is a flow diagram illustrating example operations 800 for signal amplification, in accordance with certain aspects of the present disclosure. The operations 800 may be performed, for example, by an amplifier such as the amplifier 400 or amplifier 700.

At block 802, the amplifier charges a first capacitive element (e.g., capacitive element C_{LN} of FIG. 4) coupled to a first output (Vₒₙ node) of the amplifier during a charging phase. At block 804, the amplifier generates a first current (e.g., Ion, which may be proportional to an input voltage) via a transconductance amplifier (e.g., amplifier 402) including a first flipped source follower circuit (e.g., FSF circuit 404). At block 806, the amplifier discharges the first capacitive element using the first current during a discharging phase.

In some aspects, charging the first capacitive element may include closing a first switch (e.g., implemented via transistor M_{SWTP}) coupled between a voltage rail (e.g., Vdd) and the first output of the amplifier, and discharging the first capacitive element may include closing a second switch (e.g., implemented via transistor M_{SWBP}) coupled between the first capacitive element and the transconductance amplifier.

In some aspects, the amplifier may charge a second capacitive element (e.g., C_{LP}) coupled to a second output (e.g., Vₒₚ node) of the amplifier during the charging phase and generate a second current (e.g., Iop) via the transconductance amplifier including a second flipped source follower circuit (e.g., FSF circuit 406). The amplifier may discharge the second capacitive element using the second current during the discharging phase. Charging the second capacitive element may include closing a second switch (e.g., implemented via transistor M_{SWTN}) coupled between a voltage rail and the second output of the amplifier, and discharging the second capacitive element may include closing a second switch (e.g., implemented via transistor M_{SWBN}) coupled between the second capacitive element and the transconductance amplifier.

In some aspects, the amplifier activates the transconductance amplifier. The discharging phase may occur a time period (e.g., a delay) after the transconductance amplifier is activated. In some aspects, the amplifier sources, via a current source (e.g., implemented via transistor M_{IB}), a third current to power the first flipped source follower circuit and the second flipped source follower circuit. The first current and the second current may be generated based on the third current. In some aspects, the amplifier electrically shorts (e.g., via transistor M_{SB}) the first output to the second output during the charging phase.

### Example Aspects

In addition to the various aspects described above, specific combinations of aspects are within the scope of the present disclosure, some of which are detailed below:

Aspect 1: An amplifier, comprising: a first capacitive element coupled to a first output of the amplifier; a first switch coupled between the first capacitive element and a voltage rail; a transconductance amplifier including a first flipped source follower circuit; and a second switch coupled between the first capacitive element and the transconductance amplifier.

Aspect 2: The amplifier of Aspect 1, wherein the transconductance amplifier comprises an input transistor coupled between the second switch and the first flipped source follower circuit.

Aspect 3: The amplifier of Aspect 2, wherein a gate of the input transistor is coupled to a first input of the amplifier.

Aspect 4: The amplifier of Aspect 3, wherein the first flipped source follower circuit is coupled to a second input of the amplifier, the first input and the second input forming a differential input pair for the amplifier.

Aspect 5: The amplifier according to any of Aspects 2-4, wherein the first flipped source follower circuit comprises: a first current source; a source follower transistor coupled between the first current source and an output of the first flipped source follower circuit, the output of the first flipped source follower circuit being coupled to a source of the input transistor; and a feedback transistor having a gate coupled to a drain of the source follower transistor and having a drain coupled to a source of the source follower transistor.

Aspect 6: The amplifier of Aspect 5, wherein the first flipped source follower circuit further comprises a second current source, a source of the feedback transistor being coupled to the second current source.

Aspect 7: The amplifier according to any of Aspects 1-6, further comprising: a second capacitive element coupled to a second output of the amplifier; a third switch coupled between the second capacitive element and the voltage rail; and a fourth switch coupled between the second capacitive element and the transconductance amplifier.

Aspect 8: The amplifier of Aspect 7, further comprising a fifth switch coupled between the first output and the second output of the amplifier.

Aspect 9: The amplifier according to any of Aspects 1-8, wherein the transconductance amplifier further comprises a second flipped source follower circuit, and wherein the first flipped source follower circuit and the second flipped source follower circuit share a common current source.

Aspect 10: The amplifier of Aspect 9, wherein the common current source is coupled to a source follower of the first flipped source follower circuit through a first resistive element and is coupled to a source follower of the second flipped source follower circuit through a second resistive element.

Aspect 11: The amplifier according to any of Aspects 1-10, wherein: the first switch is configured to be closed during a charging phase of the amplifier to charge the first capacitive element; and the second switch is configured to be closed during a discharging phase of the amplifier to discharge the first capacitive element.

Aspect 12: The amplifier of Aspect 11, wherein the transconductance amplifier is configured to be activated, and wherein the second switch is configured to be closed a time period after the transconductance amplifier is activated.

Aspect 13: A method for signal amplification, comprising: charging a first capacitive element coupled to a first output of an amplifier during a charging phase of the amplifier; generating a first current via a transconductance amplifier including a first flipped source follower circuit; and discharging the first capacitive element using the first current during a discharging phase of the amplifier.

Aspect 14: The method of Aspect 13, wherein: charging the first capacitive element comprises closing a first switch coupled between a voltage rail and the first capacitive element; and discharging the first capacitive element comprises closing a second switch coupled between the first capacitive element and the transconductance amplifier.

a Aspect 15: The method of Aspect 13 or 14, further comprising: charging second capacitive element coupled to a second output of the amplifier during the charging phase; generating a second current via the transconductance amplifier, the transconductance amplifier further including a second flipped source follower circuit; and discharging the second capacitive element using the second current during the discharging phase.

Aspect 16: The method of Aspect 15, wherein: charging the second capacitive element comprises closing a second switch coupled between a voltage rail and the second capacitive element; and discharging the second capacitive element comprises closing a second switch coupled between the second capacitive element and the transconductance amplifier.

Aspect 17: The method of Aspect 15 or 16, further comprising activating the transconductance amplifier, wherein the discharging phase occurs a time period after the transconductance amplifier is activated.

Aspect 18: The method according to any of Aspects 15-17, further comprising sourcing, via a current source, a third current to power the first flipped source follower circuit and the second flipped source follower circuit, wherein the first current and the second current are generated based on the third current.

Aspect 19: The method according to any of Aspects 15-18, further comprising electrically shorting the first output to the second output during the charging phase.

Aspect 20: An apparatus for signal amplification, comprising: a memory; and one or more processors coupled to the memory, the one or more processors being configured to: control a first switch coupled between a capacitive element and a voltage rail to charge a capacitive element during a charge phase; activate a transconductance amplifier including a flipped source follower circuit to generate a current; and control a second switch coupled between the capacitive element and the transconductance amplifier to discharge the capacitive element using the current.

### Additional Considerations

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An amplifier, comprising:
a first capacitive element coupled to a first output of the amplifier;
a first switch coupled between the first capacitive element and a voltage rail;
a transconductance amplifier including a first flipped source follower circuit; and
a second switch coupled between the first capacitive element and the transconductance amplifier.

2. The amplifier of claim 1, wherein the transconductance amplifier comprises an input transistor coupled between the second switch and the first flipped source follower circuit.

3. The amplifier of claim 2, wherein a gate of the input transistor is coupled to a first input of the amplifier.

4. The amplifier of claim 3, wherein the first flipped source follower circuit is coupled to a second input of the amplifier, the first input and the second input forming a differential input pair for the amplifier.

5. The amplifier of claim 2, wherein the first flipped source follower circuit comprises:
a first current source;
a source follower transistor coupled between the first current source and an output of the first flipped source follower circuit, the output of the first flipped source follower circuit being coupled to a source of the input transistor; and
a feedback transistor having a gate coupled to a drain of the source follower transistor and having a drain coupled to a source of the source follower transistor.

6. The amplifier of claim 5, wherein the first flipped source follower circuit further comprises a second current source, a source of the feedback transistor being coupled to the second current source.

7. The amplifier of claim 1, further comprising:
a second capacitive element coupled to a second output of the amplifier;
a third switch coupled between the second capacitive element and the voltage rail; and
a fourth switch coupled between the second capacitive element and the transconductance amplifier.

8. The amplifier of claim 7, further comprising a fifth switch coupled between the first output and the second output of the amplifier.

9. The amplifier of claim 1, wherein the transconductance amplifier further comprises a second flipped source follower circuit, and wherein the first flipped source follower circuit and the second flipped source follower circuit share a common current source.

10. The amplifier of claim 9, wherein the common current source is coupled to a source follower of the first flipped source follower circuit through a first resistive element and is coupled to a source follower of the second flipped source follower circuit through a second resistive element.

11. The amplifier of claim 1, wherein:
the first switch is configured to be closed during a charging phase of the amplifier to charge the first capacitive element; and
the second switch is configured to be closed during a discharging phase of the amplifier to discharge the first capacitive element.

12. The amplifier of claim 11, wherein the transconductance amplifier is configured to be activated, and wherein the second switch is configured to be closed a time period after the transconductance amplifier is activated.

13. A method for signal amplification, comprising:
charging a first capacitive element coupled to a first output of an amplifier during a charging phase of the amplifier;
generating a first current via a transconductance amplifier including a first flipped source follower circuit; and
discharging the first capacitive element using the first current during a discharging phase of the amplifier.

14. The method of claim 13, wherein:
charging the first capacitive element comprises closing a first switch coupled between a voltage rail and the first capacitive element; and
discharging the first capacitive element comprises closing a second switch coupled between the first capacitive element and the transconductance amplifier.

15. The method of claim 13, further comprising:
charging a second capacitive element coupled to a second output of the amplifier during the charging phase;
generating a second current via the transconductance amplifier, the transconductance amplifier further including a second flipped source follower circuit; and
discharging the second capacitive element using the second current during the discharging phase.

16. The method of claim 15, wherein:
charging the second capacitive element comprises closing a second switch coupled between a voltage rail and the second capacitive element; and
discharging the second capacitive element comprises closing a second switch coupled between the second capacitive element and the transconductance amplifier.

17. The method of claim 15, further comprising activating the transconductance amplifier, wherein the discharging phase occurs a time period after the transconductance amplifier is activated.

18. The method of claim 15, further comprising sourcing, via a current source, a third current to power the first flipped source follower circuit and the second flipped source follower circuit, wherein the first current and the second current are generated based on the third current.

19. The method of claim 15, further comprising electrically shorting the first output to the second output during the charging phase.

20. An apparatus for signal amplification, comprising:
a memory; and
one or more processors coupled to the memory, the one or more processors being configured to:
control a first switch coupled between a capacitive element and a voltage rail to charge a capacitive element during a charge phase;
activate a transconductance amplifier including a flipped source follower circuit to generate a current; and
control a second switch coupled between the capacitive element and the transconductance amplifier to discharge the capacitive element using the current.
